(19) United States
(12) Patent Application Publication
(10) Pub. No.: US 2025/0087530 A1
(43) Pub. Date: Mar. 13, 2025

(54) LATERAL ETCHING PROCESS TO REMOVE METAL GATE FOOT STRUCTURES

(71) Applicant: Intel Corporation, Santa Clara, CA (US)

(72) Inventors: Chiao-Ti Huang, Portland, OR (US); Tao Chu, Portland, OR (US); Guowei Xu, Portland, OR (US); Robin Chao, Portland, OR (US); Feng Zhang, Hillsboro, OR (US); Yang Zhang, Rio Rancho, NM (US); Ting-Hsiang Hung, Beaverton, OR (US); Anand Murthy, Portland, OR (US)

(73) Assignee: Intel Corporation, Santa Clara, CA (US)

(21) Appl. No.: 18/463,436

(22) Filed: Sep. 8, 2023

(51) Int. Cl. H01L 21/762; H01L 21/768; H01L 23/48; H01L 27/088; H01L 27/12

(52) U.S. Cl. CPC H01L 21/76232; H01L 21/76898; H01L 23/481; H10D 84/83; H10D 86/00; H01L 24/16; H01L 2224/16235

(57) ABSTRACT

Techniques are provided to form semiconductor devices where portions of the gate structure (e.g., foot structures) adjacent to the subfins have been removed. A semiconductor device includes a gate structure around or otherwise on a semiconductor region. The gate structure includes a gate dielectric and a gate electrode. The gate structure may be interrupted, for example, between two transistors with a gate cut that extends through an entire thickness of the gate structure and includes dielectric material to electrically isolate the portions of the gate structure on either side of the gate cut. The gate cut includes dielectric lobe structures that extend outwards from the sidewalls of the gate cut. The lobe structures effectively replace foot structures of the gate structure between the gate cut and subfin portions of the semiconductor fins. Removing the gate foot structures contributes to the reduction of the parasitic capacitance in the semiconductor device.

### BACKGROUND

As integrated circuits continue to scale downward in size, a number of challenges arise. For instance, reducing the size of memory and logic cells is becoming increasingly more difficult, as is reducing device spacing at the device layer. As transistors are packed more densely, parasitic effects can increasingly impact the device operation in an undesirable way. Accordingly, there remain a number of non-trivial challenges with respect to forming semiconductor devices.

### BRIEF DESCRIPTION OF THE DRAWINGS

FIGS. 1A and 1B are cross-sectional and plan views, respectively, of some semiconductor devices that illustrate the absence of metal gate foot structures, in accordance with an embodiment of the present disclosure.

FIGS. 2A-2P are cross-sectional views that illustrate various stages in an example process for forming semiconductor devices that have their metal gate foot structures removed, in accordance with some embodiments of the present disclosure.

FIG. 3 illustrates a cross-sectional view of a chip package containing one or more semiconductor dies, in accordance with some embodiments of the present disclosure.

FIG. 4 is a flowchart of a fabrication process for removing the metal gate foot structures on semiconductor devices, in accordance with an embodiment of the present disclosure.

FIG. 5 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein to form semiconductor devices where portions of the gate structure (e.g., foot structures) adjacent to the subfins have been removed. The techniques can be used in any number of integrated circuit applications and are particularly useful with respect to device layer transistors, such as finFETs or gate-all-around transistors (e.g., ribbonFETs and nanowire FETs). In an example, a semiconductor device includes a gate structure around or otherwise on a semiconductor region. The semiconductor region can be, for example, a fin of semiconductor material that extends from a source region to a drain region, or one or more nanowires or nanoribbons or nanosheets of semiconductor material that extend from a source region to a drain region. The gate structure includes a gate dielectric (e.g., high-k gate dielectric material) and a gate electrode (e.g., conductive material such as workfunction material and/or gate fill metal). The gate structure may be interrupted, for example, between two transistors with a gate cut that extends through an entire thickness of the gate structure and includes dielectric material to electrically isolate the portions of the gate structure on either side of the gate cut. The gate cut includes dielectric lobe structures that extend outwards from the sidewalls of the gate cut. The lobe structures effectively replace foot structures of the gate structure between the gate cut and subfin portions of the semiconductor fins. Removing the gate foot structures contributes to the reduction of the parasitic capacitance in the semiconductor device. Numerous variations and embodiments will be apparent in light of this disclosure.

### General Overview

As previously noted above, there remain a number of non-trivial challenges with respect to integrated circuit fabrication. In more detail, as devices become smaller and more densely packed, many structures become more challenging to fabricate as critical dimensions (CD) of the structures push the limits of current fabrication technology. In one example, due to some fabrication side effects, metal gate structures can extend below a top surface of and adjacent to subfin regions beneath semiconductor regions of the devices. This extension of the metal gate structures effectively pushes down the dielectric fill between the subfin regions. The dielectric fill acts as shallow trench isolation (STI) between adjacent semiconductor devices. This leads to conductive ‘foot’ structures on both sides of the subfin that do not positively contribute to the transistor current while increasing the parasitic capacitance in the device. In operation, these parasitic effects can reduce the switching speed of the transistors and degrade the overall performance. One possible solution to avoid or reduce gated subfins is to reduce the frontside shallow trench isolation (STI) recess etch and gate oxide clean during metal gate processing. However, an STI recess that is too shallow may block part of the channel region, such as one or more of the lower ribbons or wires in gate-all-around channel configuration. Furthermore, the presence of the foot structures increases the chance of shorting with a conductive via extending through a full thickness of the gate structure.

Thus, and in accordance with an embodiment of the present disclosure, techniques are provided herein to remove the conductive foot structures while maintaining the rest of the gate structure. According to some embodiments, a gate cut extends through an entire thickness of the gate structure and adjacent to a semiconductor fin of a given semiconductor device. The fin may include a series of nanoribbons, which the gate structure extends around, and a subfin flanked by a dielectric layer. The gate cut may also extend through an entire thickness, or at least a portion of the entire thickness, of the dielectric layer. According to some embodiments, the gate cut includes a dielectric lobe structure that extends away from a sidewall of the gate cut such that a top portion of the lobe structure contacts the gate structure and a bottom portion of the lobe structure contacts the dielectric layer. A distal end of the lobe structure may also contact the subfin. The lobe structure may include a same arrangement of dielectric materials as the remainder of the gate cut. For example, the lobe structure may include a dielectric liner along edges of the lobe structure and a dielectric fill within a remaining volume of the lobe structure and on the dielectric liner. The dielectric liner may include a dielectric material with a higher dielectric constant compared to that of a dielectric material of the dielectric fill. Note that the gate cut can refer to a fully dielectric structure that separates two gate structures from one another or to a dielectric structure that includes a conductive via extending through the middle of and along an entire thickness of the dielectric structure.

According to some embodiments, following the formation of a gate cut recess through an entire thickness of the gate structure and into at least a portion of the dielectric layer, a sacrificial material is formed within the gate cut recess and recessed until a top surface of the sacrificial material is level with or below a top surface of the subfin. A sacrificial layer is then deposited over the exposed sidewalls of the gate cut recess and on a top surface of the sacrificial material within the gate cut recess. The sacrificial material is then removed to expose lower sidewall portions of the gate cut recess not protected by the sacrificial layer. The exposed lower sidewall portions include exposed portions of the gate foot structures. Accordingly, an isotropic etching process may be performed to laterally etch away the gate foot structures while the other portions of the gate structure are protected by the sacrificial layer. Once all sacrificial layers and materials are removed from the gate cut recess, it is filled with one or more dielectric materials. The dielectric materials are also formed within the etched region of the gate structure, thus forming a dielectric lobe structure, according to some embodiments.

According to an embodiment, an integrated circuit includes a semiconductor region extending from a source or drain region in a first direction, a gate structure extending over the semiconductor region in a second direction different from the first direction, a dielectric layer beneath the gate structure, and a dielectric structure extending in the first direction through the gate structure adjacent to the semiconductor region and extending in a third direction through an entire thickness of the gate structure and through at least a portion of an entire thickness of the dielectric layer. The dielectric structure includes walls that extend substantially in the third direction and abut the gate structure and one or more lobe structures that extend from the walls in the second direction such that a top portion of the one or more lobe structures contacts the gate structure and a bottom portion of the one or more lobe structures contacts the dielectric layer.

According to an embodiment, an integrated circuit includes a semiconductor region extending from a source or drain region in a first direction, a gate structure extending over the semiconductor region in a second direction different from the first direction, a dielectric layer beneath the gate structure, a dielectric structure extending in the first direction through the gate structure adjacent to the semiconductor region and extending in a third direction through an entire thickness of the gate structure and through at least a portion of an entire thickness of the dielectric layer, and a conductive via extending through an entire thickness of the dielectric structure in the third direction. The dielectric structure includes walls extending substantially in the third direction and at least one lobe structure extending in the second direction from at least one of the walls. The dielectric structure also includes a dielectric liner along an outer edge of the walls and the at least one lobe structure of the dielectric structure and a dielectric fill on the dielectric liner.

According to another embodiment, a method of forming an integrated circuit includes forming a multilayer fin extending in a first direction over a substrate having a first section with first material layers alternating with second material layers, and a subfin beneath the first section; forming a dielectric layer adjacent to the subfin; forming a gate structure extending in a second direction over the first material layers after removing the second material layers of the multilayer fin, wherein a portion of the gate structure extends below a top surface of the subfin; forming a recess adjacent to the first material layers and the subfin and through an entire thickness of the gate structure and at least a portion of an entire thickness of the dielectric layer; forming a sacrificial material at a bottom portion of the recess, such that a top surface of the sacrificial material is below a top surface of the subfin; forming a sacrificial liner above the sacrificial material on sidewalls within the recess; removing the sacrificial material; removing the portion of the gate structure extending below the top surface of the subfin; removing the sacrificial liner; and forming one or more dielectric materials within the recess.

The techniques can be used with any type of non-planar transistors, including finFETs (sometimes called tri-gate transistors), nanowire and nanoribbon transistors (sometimes called gate-all-around transistors), or forksheet transistors, to name a few examples. The source and drain regions can be, for example, doped portions of a given fin or substrate, or epitaxial regions that are deposited during an etch-and-replace source/drain forming process. The dopant-type in the source and drain regions will depend on the polarity of the corresponding transistor. The gate structure can be implemented with a gate-first process or a gate-last process (sometimes called a replacement metal gate, or RMG, process). Any number of semiconductor materials can be used in forming the transistors, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate the presence of a dielectric lobe structure extending outwards from the sidewall of a gate cut. Furthermore, the lobe structure may be observed as replacing a region of the gate structure (e.g., adjacent to a top portion of the subfin) where a gate foot structure would have existed. Numerous configurations and variations will be apparent in light of this disclosure.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” “top,” “bottom,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the materials has an element that is not in the other material.

### Architecture

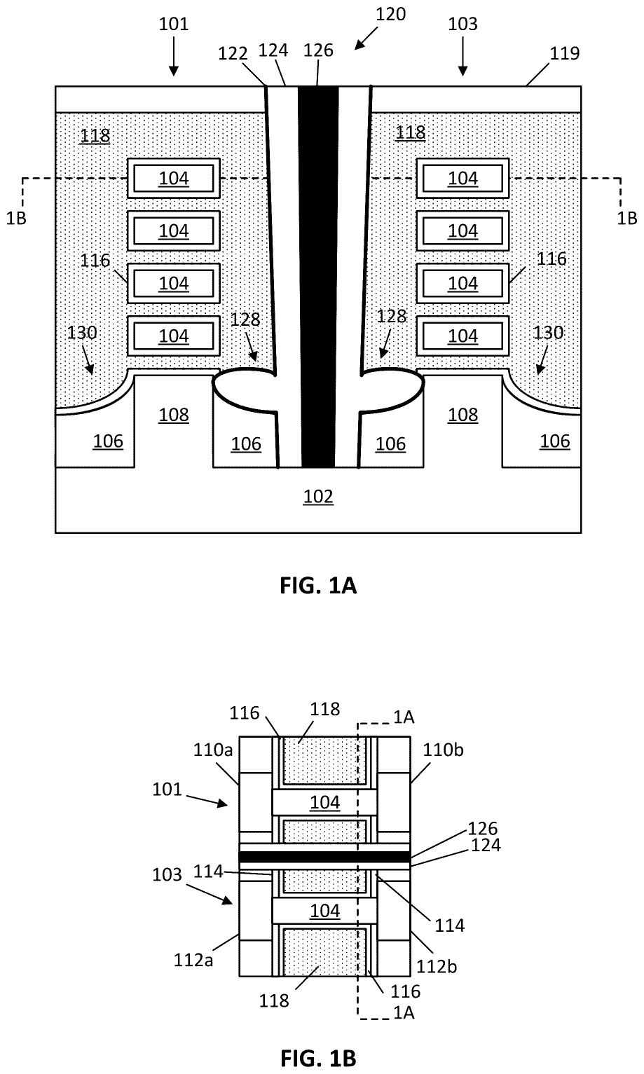

FIG. 1A is a cross-sectional view taken across two example semiconductor devices 101 and 103, according to an embodiment of the present disclosure. FIG. 1B is a top-down cross-section view of the adjacent semiconductor devices 101 and 103 taken across the dashed line 1B-1B depicted in FIG. 1A, and FIG. 1A illustrates the cross-section taken across the dashed line 1A-1A depicted in FIG. 1B. It should be noted that some of the material layers (such as gate cap 119) are not visible in the top-down view of FIG. 1B, given the location of the depicted cross-section. Each of semiconductor devices 101 and 103 may be non-planar metal oxide semiconductor (MOS) transistors, such as tri-gate (e.g., finFET) or gate-all-around (GAA) transistors, although other transistor topologies and types could also benefit from the gate cut techniques and structures provided herein. The illustrated example embodiments herein use the GAA structure. Semiconductor devices 101 and 103 represent a portion of an integrated circuit that may contain any number of similar semiconductor devices.

As can be seen, semiconductor devices 101 and 103 are formed on a substrate 102. Any number of semiconductor devices can be formed on substrate 102, but two are used here as an example. Substrate 102 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, substrate 102 can be a semiconductor-on-insulator substrate having a desired semiconductor layer over a buried insulator layer (e.g., silicon over silicon dioxide). Alternatively, substrate 102 can be a multilayer substrate or superlattice suitable for forming nanowires or nanoribbons (e.g., alternating layers of silicon and SiGe, or alternating layers indium gallium arsenide and indium phosphide). Any number of substrates can be used. In some example embodiments, a lower portion of (or all of) substrate 102 is removed and replaced with one or more backside interconnect layers to form backside signal and power routing.

Each of semiconductor devices 101 and 103 includes one or more nanoribbons 104 that extend parallel to one another along a direction between a source region and a drain region (e.g., a first direction into and out of the page in the cross-section view of FIG. 1A). Nanoribbons 104 are one example of semiconductor regions or semiconductor bodies that extend between source and drain regions. The term nanoribbon may also encompass other similar shapes such as nanowires or nanosheets. The semiconductor material of nanoribbons 104 may be formed from substrate 102. In some embodiments, semiconductor devices 101 and 103 may each include semiconductor regions in the shape of fins that can be, for example, native to substrate 102 (formed from the substrate itself), such as silicon fins etched from a bulk silicon substrate. Alternatively, the fins can be formed of material deposited onto an underlying substrate. In one such example case, a blanket layer of silicon germanium (SiGe) can be deposited onto a silicon substrate, and then patterned and etched to form a plurality of SiGe fins extending from that substrate. In another such example, non-native fins can be formed in a so-called aspect ratio trapping based process, where native fins are etched away so as to leave fin-shaped trenches which can then be filled with an alternative semiconductor material (e.g., group IV or III-V material). In still other embodiments, the fins include alternating layers of material (e.g., alternating layers of silicon and SiGe) that facilitates forming of the illustrated nanoribbons 104 during a gate forming process where one type of the alternating layers is selectively etched away so as to liberate the other type of alternating layers within the channel region, so that a gate-all-around (GAA) process can then be carried out. Again, the alternating layers can be blanket deposited and then etched into fins or deposited into fin-shaped trenches, according to some examples.

As can further be seen, adjacent semiconductor devices are separated by a dielectric fill 106 that may include silicon dioxide. Dielectric fill 106 provides shallow trench isolation (STI) between any adjacent semiconductor devices, and adjacent subfin regions 108. Dielectric fill 106 can be any suitable dielectric material, such as silicon dioxide, aluminum oxide, or silicon oxycarbonitride.

Semiconductor devices 101 and 103 each include a subfin region 108, in this example. According to some embodiments, subfin region 108 comprises the same semiconductor material as substrate 102 and is adjacent to dielectric fill 106. In some embodiments, the semiconductor material of subfin region 108 is removed (e.g., from a backside process) and replaced with one or more dielectric materials. According to some embodiments, nanoribbons 104 (or other semiconductor bodies) extend between a source and a drain region in the first direction to provide an active region for a transistor (e.g., the semiconductor region beneath the gate). The source and drain regions are not shown in the cross-section of FIG. 1A, but are seen in the top-down view of FIG. 1B where nanoribbons 104 of semiconductor device 101 extend between a first source or drain region 110a and a second source or drain region 110b (similarly, the nanoribbons 104 of semiconductor device 103 extend between a first source or drain region 112a and a second source or drain region 112b). FIG. 1B also illustrates spacer structures 114 that extend around the ends of nanoribbons 104 and along sidewalls of the gate structures between spacer structures 114. Spacer structures 114 may include a dielectric material, such as silicon nitride.

According to some embodiments, the source and drain regions are epitaxial regions that are provided using an etch-and-replace process. In other embodiments one or both of the source and drain regions could be, for example, implantation-doped native portions of the semiconductor fins or substrate. Any semiconductor materials suitable for source and drain regions can be used (e.g., group IV and group III-V semiconductor materials). The source and drain regions may include multiple layers such as liners and capping layers to improve contact resistance. In any such cases, the composition and doping of the source and drain regions may be the same or different, depending on the polarity of the transistors. In an example, for instance, one transistor is a p-type MOS (PMOS) transistor, and the other transistor is an n-type MOS (NMOS) transistor. Any number of source and drain configurations and materials can be used.

According to some embodiments, a first gate structure extends over nanoribbons 104 of semiconductor device 101 along a second direction across the page while a second gate structure extends over nanoribbons 104 of semiconductor device 103 along the second direction. The second direction may be orthogonal to the first direction. Each gate structure includes a respective gate dielectric 116 and a gate electrode (or gate layer) 118. Gate dielectric 116 represents any number of dielectric layers present between nanoribbons 104 and gate electrode 118. Gate dielectric 116 may also be present on the surfaces of other structures within the gate trench, such as on subfin region 108 and dielectric fill 106. Gate dielectric 116 may include any suitable gate dielectric material(s). In some embodiments, gate dielectric 116 includes a layer of native oxide material (e.g., silicon dioxide) on the nanoribbons or other semiconductor regions making up the channel region of the devices, and a layer of high-K dielectric material (e.g., hafnium oxide) on the native oxide.

Gate electrode 118 may represent any number of conductive layers, such as any metal, metal alloy, or doped polysilicon layers. In some embodiments, gate electrode 118 includes one or more workfunction metals around nanoribbons 104. In some embodiments. one of semiconductor devices 101 and 103 is a p-channel device that include a workfunction metal having titanium around its nanoribbons 104 and the other semiconductor device is an n-channel device that includes a workfunction metal having tungsten around its nanoribbons 104. Gate electrode 118 may also include a fill metal or other conductive material (e.g., tungsten, ruthenium, molybdenum, copper, aluminum) around the workfunction metals to provide the whole gate electrode structure. In some embodiments, a gate cap 119 may be formed over gate electrode 118 to protect the underlying material during processing. Gate cap 119 may be any suitable dielectric material, such as silicon nitride.

According to some embodiments, adjacent gate structures may be separated along the second direction (e.g., across the page) by a gate cut 120, which acts like a dielectric barrier or wall between gate structures. Accordingly, gate cut 120 may represent any dielectric structure that extends in a first direction across a gate trench (separating two gate structures) and extends in a third direction (e.g., vertically) through at least an entire thickness of the gate structure. In some embodiments, gate cut 120 also extends through an entire thickness of dielectric fill 106. According to some embodiments, gate cut 120 may include one or more dielectric materials and may include a conductive via passing through its center and along its entire thickness in the third direction. For example, gate cut 120 includes a dielectric liner 122 along an outer edge of gate cut 120 and a dielectric fill 124 on dielectric liner 122. According to some embodiments, dielectric liner 122 includes a high-k dielectric material, such as silicon nitride or aluminum oxide, and dielectric fill 124 includes a low-k dielectric material, such as silicon dioxide, porous silicon dioxide, or flowable oxide. Dielectric liner 122 may be conformal and have a thickness between about 2 nm and about 4 nm. Gate cut 120 may have a top width along the second direction between about 40 nm and about 70 nm.

According to some embodiments, gate cut 120 includes a conductive via 126 extending through a central portion of gate cut 120. Conductive via 126 may be aligned directly along a central axis of gate cut 120 extending in the third direction, or may be misaligned closer to one sidewall of gate cut 120. As noted above, conductive via 126 extends through an entire thickness of gate cut 120 in order to connect with a backside conductive layer (e.g., beneath dielectric fill 106) for power or signal routing. Conductive via 126 may include any suitable conductive material, such as tungsten, ruthenium, molybdenum, or cobalt.

According to some embodiments, gate cut 120 includes one or more lobe structures 128 that extend away from its otherwise straight sidewalls. Lobe structures 128 include the same or similar dielectric materials to the columnar regions of gate cut 120. Accordingly, lobe structures 128 may include dielectric liner 122 along the outer edges of lobe structures 128 and dielectric fill 124 within a remaining volume of lobe structures 128. According to some embodiments, lobe structures 128 replace portions of the gate structures (e.g., gate foot structures) that extended below the top surface of subfins 108. Example gate foot structures 130 are illustrated on the opposite sides of subfins 108 for context. A distal end of lobe structures 128 may contact subfins 108. According to some embodiments, a top surface of lobe structures 128 abuts gate electrode 118 and a bottom surface of lobe structures 128 abuts dielectric fill 106. The replacement of the gate foot structures with lobe structures 128 reduces the parasitic capacitance of the devices and reduces the risk of shorting between gate electrode 118 and conductive via 126.

According to some embodiments, gate cut 120 extends in the first direction as seen in FIG. 1B such that it cuts across at least the entire width of the gate trench. According to some embodiments, gate cut 120 may also extend further past spacer structures 114. In some examples, gate cut 120 extends across more than one gate trench in the first direction (e.g., cutting through more than one gate structure running parallel along the second direction).

### Fabrication Methodology

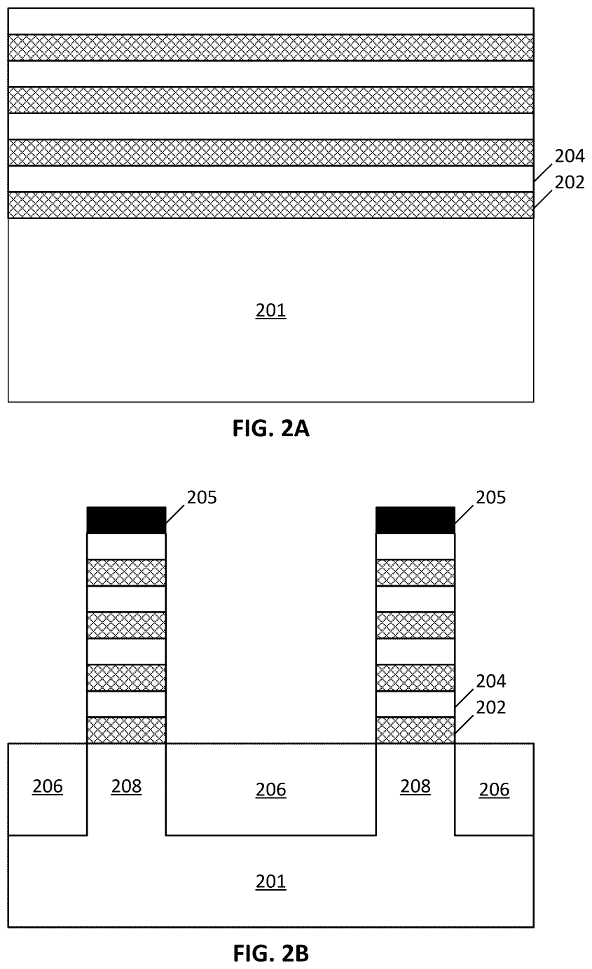

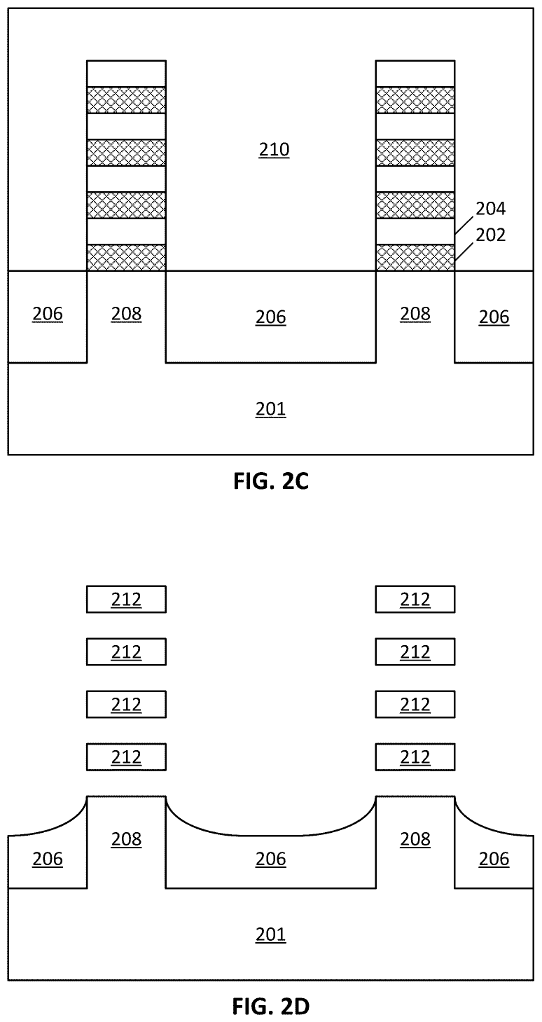

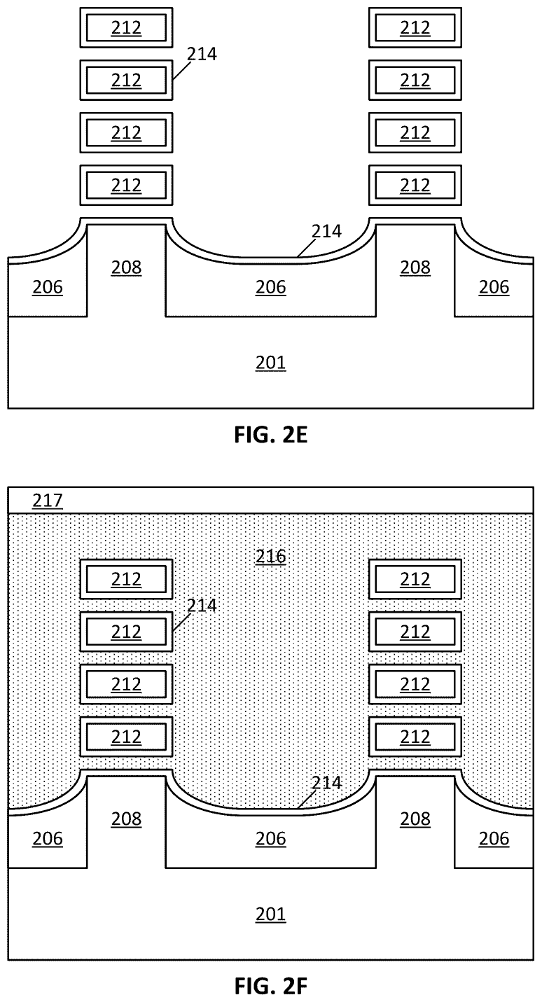

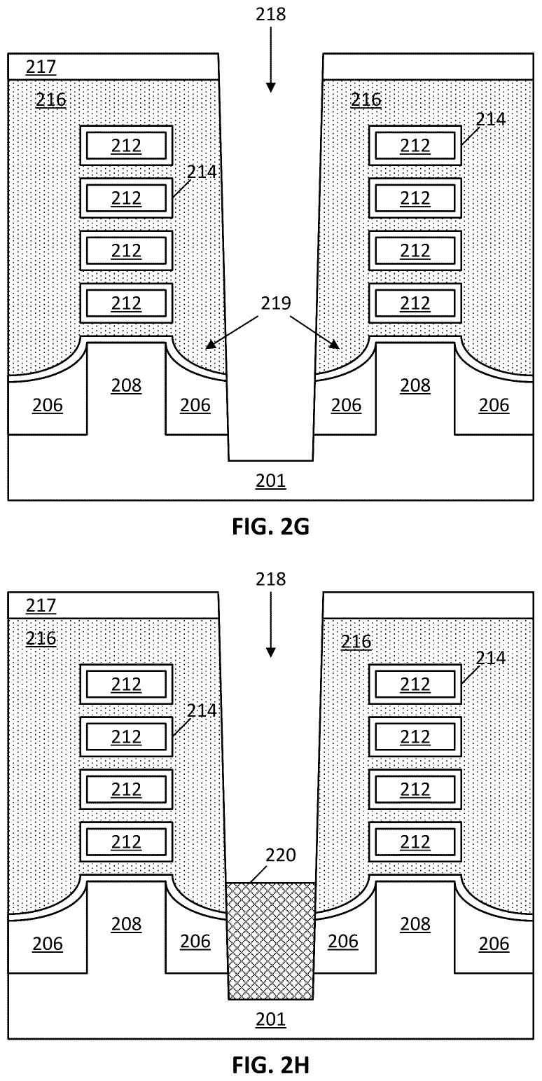

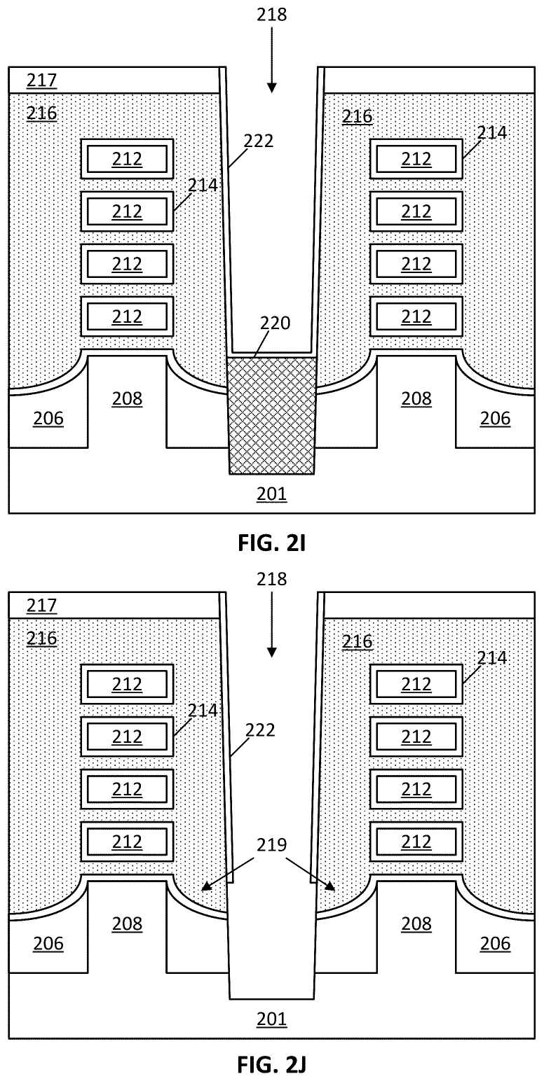

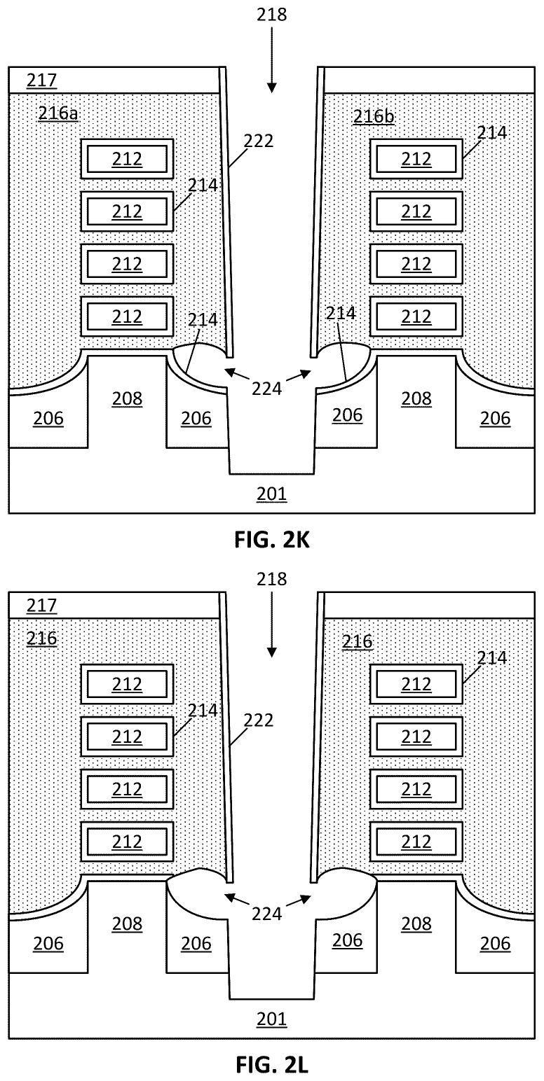

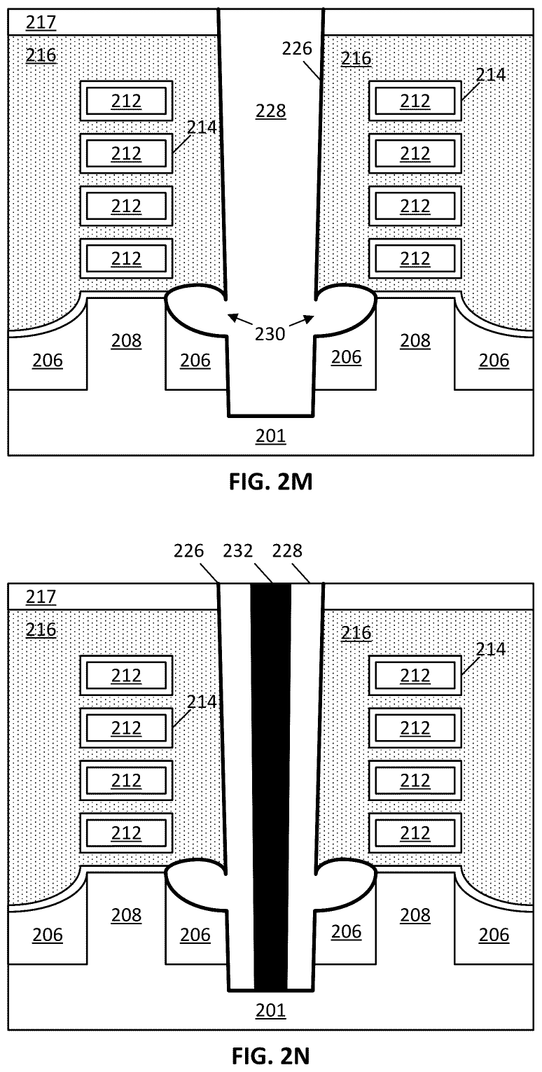

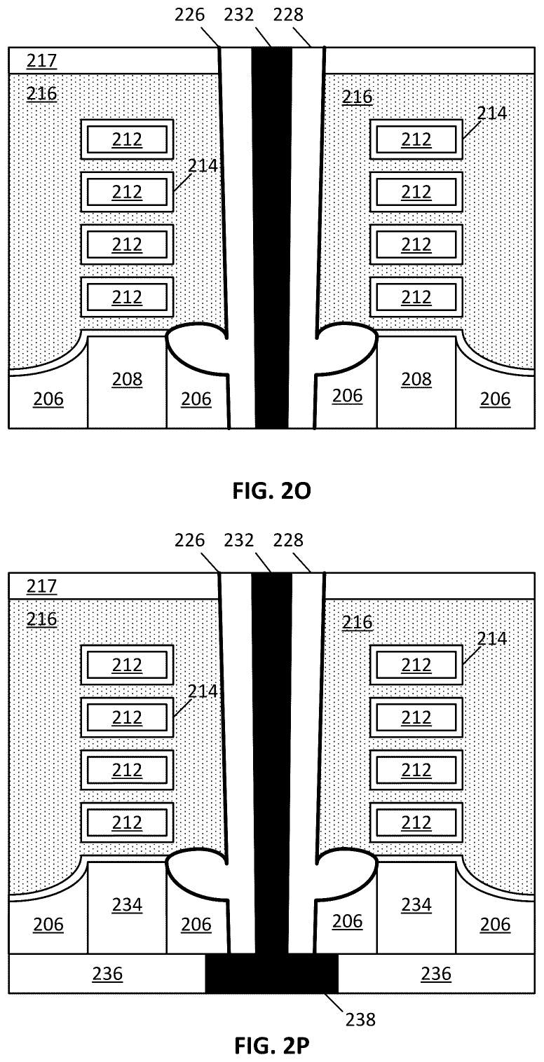

FIGS. 2A-2P include cross-sectional views that collectively illustrate an example process for forming an integrated circuit with semiconductor devices that have their metal gate foot structures removed and replaced with dielectric lobe structures, in accordance with an embodiment of the present disclosure. Each figure shows an example structure that results from the process flow up to that point in time, so the depicted structure evolves as the process flow continues, culminating in the structure shown in FIG. 2P, which is similar to the structure shown in FIG. 1A. The illustrated integrated circuit structure may be part of a larger integrated circuit that includes other integrated circuitry not depicted. Example materials and process parameters are given, but the present disclosure is not intended to be limited to any specific such materials or parameters, as will be appreciated. Although the fabrication of a single gate cut is illustrated in the aforementioned figures, it should be understood that any number of similar gate cuts can be fabricated across the integrated circuit using the same processes discussed herein.

FIG. 2A illustrates a cross-sectional view taken through a substrate 201 having a series of material layers formed over the substrate, according to an embodiment of the present disclosure. Alternating material layers may be deposited over substrate 201 including sacrificial layers 202 alternating with semiconductor layers 204. The alternating layers are used to form GAA transistor structures. Any number of alternating semiconductor layers 204 and sacrificial layers 202 may be deposited over substrate 201. The description above for substrate 102 applies equally to substrate 201.

According to some embodiments, sacrificial layers 202 have a different material composition than semiconductor layers 204. In some embodiments, sacrificial layers 202 are silicon germanium (SiGe) while semiconductor layers 204 include a semiconductor material suitable for use as a nanoribbon such as silicon (Si), SiGe, germanium, or III-V materials like indium phosphide (InP) or gallium arsenide (GaAs). In examples where SiGe is used in each of sacrificial layers 202 and in semiconductor layers 204, the germanium concentration is different between sacrificial layers 202 and semiconductor layers 204. For example, sacrificial layers 202 may include a higher germanium content compared to semiconductor layers 204. In some examples, semiconductor layers 204 may be doped with either n-type dopants (to produce a p-channel transistor) or p-type dopants (to produce an n-channel transistor).

While dimensions can vary from one example embodiment to the next, the thickness of each sacrificial layer 202 may be between about 5 nm and about 20 nm. In some embodiments, the thickness of each sacrificial layer 202 is substantially the same (e.g., within 1-2 nm). The thickness of each of semiconductor layers 204 may be about the same as the thickness of each sacrificial layer 202 (e.g., about 5-20 nm). Each of sacrificial layers 202 and semiconductor layers 204 may be deposited using any known or proprietary material deposition technique, such as chemical vapor deposition (CVD), plasma-enhanced chemical vapor deposition (PECVD), physical vapor deposition (PVD), or atomic layer deposition (ALD).

FIG. 2B depicts the cross-section view of the structure shown in FIG. 2A following the deposition of a cap layer 205 and the subsequent formation of fins beneath cap layer 205, according to an embodiment. Cap layer 205 may be any suitable hard mask material such as a carbon hard mask (CHM) or silicon nitride. Cap layer 205 is patterned into rows to form corresponding rows of fins from the alternating layer stack of sacrificial layers 202 and semiconductor layers 204. The rows of fins extend lengthwise in a first direction (e.g., into and out of the page).

According to some embodiments, an anisotropic etching process through the layer stack continues into at least a portion of substrate 201. The etched portion of substrate 201 may be filled with a dielectric fill 206 that acts as shallow trench isolation (STI) between adjacent fins. Dielectric fill 206 may be any suitable dielectric material such as silicon dioxide. Subfin regions 208 represent remaining portions of substrate 201 between dielectric fill 206, according to some embodiments.

FIG. 2C depicts the cross-section view of the structure shown in FIG. 2B following the formation of a sacrificial gate 210 extending across the fins in a second direction different from the first direction, according to some embodiments. Sacrificial gate 210 may extend across the fins in a second direction that is orthogonal to the first direction. According to some embodiments, the sacrificial gate material is formed in parallel strips across the integrated circuit and removed in all areas not protected by a gate masking layer. Sacrificial gate 210 may be any suitable material that can be selectively removed without damaging the semiconductor material of the fins. In some examples, sacrificial gate 210 includes polysilicon. In some cases, sacrificial gate 210 may also include a gate dielectric. such as an oxide of the fin material.

Following the formation of sacrificial gate 210 (and prior to replacement of sacrificial gate 210 with a metal gate), additional semiconductor device structures are formed that are not shown in these cross-sections. These additional structures include spacer structures on the sidewalls of sacrificial gate 210 and source and drain regions on either ends of each of the fins. The formation of such structures can be accomplished using any number of processing techniques.

FIG. 2D depicts the cross-section view of the structure shown in FIG. 2C following the removal of sacrificial gate 210 and the removal of sacrificial layers 202, according to some embodiments. In examples where any gate masking layers are still present, they may also be removed at this time. Once sacrificial gate 210 is removed, the fins that had been beneath sacrificial gate 210 are exposed.

In the example where the fins include alternating semiconductor layers, sacrificial layers 202 are selectively removed to release nanoribbons 212 that extend between corresponding source or drain regions. Each vertical set of nanoribbons 212 represents the semiconductor or channel region of a different semiconductor device. It should be understood that nanoribbons 212 may also be nanowires or nanosheets (e.g., from a forksheet arrangement) or fins (e.g., for a finFET arrangement). Sacrificial gate 210 and sacrificial layers 202 may be removed using the same isotropic etching process or different isotropic etching processes.

According to some embodiments, a top surface of dielectric fill 206 may be recessed below a top surface of subfins 208. The top surface of dielectric fill 206 may slope downwards from the sidewalls of subfins 208 to form a bowl shape as illustrated in FIG. 2D. This recessing of dielectric fill 206 may occur as a result of the etching process used to originally form dielectric fill 206 between subfins 208 and/or as a result of the etching process used to remove sacrificial gate 210 and sacrificial layers 202.

FIG. 2E depicts the cross-section view of the structure shown in FIG. 2D following the deposition of a gate dielectric 214, according to some embodiments. Gate dielectric 214 may be first formed around nanoribbons 212 prior to the deposition of any conductive layers. Gate dielectric 214 may include any suitable dielectric material (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. According to some embodiments, gate dielectric 214 includes a layer of hafnium oxide with a thickness between about 1 nm and about 5 nm. In some embodiments, gate dielectric 214 may include one or more silicates (e.g., titanium silicate, tungsten silicate, niobium silicate, and silicates of other transition metals). In some cases, gate dielectric 214 may include a first layer on nanoribbons 212, and a second layer on the first layer. The first layer can be, for instance, an oxide of the semiconductor material of nanoribbons 212 (e.g., silicon dioxide) and the second layer can be a high-k dielectric material (e.g., hafnium oxide). More generally, gate dielectric 214 can include any number of dielectric layers. According to some embodiments, gate dielectric 214 forms along all surfaces exposed within the gate trench, such as along inner sidewalls of the spacer structures and along the top surfaces of dielectric fill 206 and subfin regions 208.

FIG. 2F illustrates another cross-section view of the structure shown in FIG. 2E following the formation of a gate electrode 216 on gate dielectric 214 within the gate trench, according to some embodiments. As noted above, gate electrode 216 can represent any number of conductive layers. The conductive gate electrode 216 may be deposited using electroplating, electroless plating, CVD, PECVD, ALD, or PVD, to name a few examples. In some embodiments, gate electrode 216 includes doped polysilicon, a metal, or a metal alloy. Example suitable metals or metal alloys include aluminum, tungsten, cobalt, molybdenum, ruthenium, titanium, tantalum, copper, and carbides and nitrides thereof. Gate electrode 216 may include, for instance, a metal fill material along with one or more workfunction layers, resistance-reducing layers, and/or barrier layers. The workfunction layers can include, for example, p-type workfunction materials (e.g., titanium nitride) for PMOS gates, or n-type workfunction materials (e.g., titanium aluminum carbide) for NMOS gates. Following the formation of the gate structure (e.g., both gate dielectric 214 and gate electrode 216), the entire structure may be polished or planarized such that the top surface of the gate structure (e.g., top surface of gate electrode 216) is planar with the top surface of other semiconductor elements, such as the spacer structures that define the gate trench.

According to some embodiments, gate electrode 216 may be recessed within the gate trench and a gate cap 217 may be formed within the recess above gate electrode 216. Gate cap 217 may be a dielectric material, such as silicon nitride, for protecting the underlying gate electrode 216. In some examples, gate cap 217 has a thickness between about 10 nm and about 20 nm, such as around 15 nm.

FIG. 2G illustrates another cross-section view of the structure shown in FIG. 2F following the formation of a gate cut recess 218 through at least an entire thickness of gate electrode 216, according to some embodiments. Gate cut recess 218 may have a high height-to-width aspect ratio of 5:1 or more, such as between 6:1 and 10:1 and may be formed via a series of RIE and passivation steps to etch through the conductive material of gate electrode 216. Gate cut recess 218 may be tapered and have a largest width along a top surface of gate electrode 216 between about 40 nm and about 75 nm. In some embodiments, gate cut recess 218 extends through an entire thickness of dielectric fill 206 and into the underlying substrate 201. According to some embodiments, gate foot structures 219 are left between subfins 208 and gate cut recess 218.

FIG. 2H illustrates another cross-section view of the structure shown in FIG. 2G following the deposition of a sacrificial material 220 within gate cut recess 218, according to some embodiments. Sacrificial material 220 may be any suitable material that can be removed at a later time without damaging any surrounding materials (e.g., metal, semiconductor, or dielectric materials). In some examples, sacrificial material 220 is carbon hard mask (CHM). According to some embodiments, sacrificial material 220 is recessed within gate cut recess 218 until a top surface of sacrificial material 220 is level with or at least below a top surface of subfins 208. In some examples, sacrificial material 220 is recessed within gate cut recess 218 until the top surface of sacrificial material 220 is between the bottom surface of the bottom-most nanoribbon 212 and the top surface of subfins 208. In any case, the top surface of sacrificial material 220 is above the lowest point of the top surface of the adjacent dielectric fill 206.

FIG. 2I illustrates another cross-section view of the structure shown in FIG. 2H following the deposition of a sacrificial layer 222 within gate cut recess 218, according to some embodiments. Sacrificial layer 222 may be formed along any exposed sidewall surfaces of gate cut recess 218 above sacrificial material 220 and on a top surface of sacrificial material 220. Sacrificial layer 222 may be any suitable material that can withstand metal etchants and be removed without damaging the underlying gate electrode 216. In some examples, sacrificial layer 222 includes aluminum oxide. In some examples, sacrificial layer 222 has a thickness between about 2 nm and about 10 nm.

FIG. 2J illustrates another cross-section view of the structure shown in FIG. 2I following the removal of sacrificial material 220, according to some embodiments. An anisotropic etching process may first be performed to remove the portion of sacrificial layer 222 on the top surface of sacrificial material 220, thus exposing the top surface of sacrificial material 220 within gate cut recess 218. Next, an ashing process or any other suitable isotropic etching process may be performed to remove sacrificial material 220 from within gate cut recess 218. According to some embodiments, the removal of sacrificial material 220 exposes gate foot structures 219 beneath sacrificial layer 222.

FIG. 2K illustrates another cross-section view of the structure shown in FIG. 2J following the removal of gate foot structures 219, according to some embodiments. One or more isotropic metal etch processes may be performed to remove gate foot structures 219 and leave behind lobe recesses 224, according to some embodiments. For example, a first isotropic etching process may remove the gate foot structure associated with a first gate electrode 216a having n-channel work function metals while a second isotropic etching process may remove the gate foot structure associated with a second gate electrode 216b having p-channel work function metals, or vice versa. In any case, the etching process removes metal materials while etching comparatively little of gate dielectric 214, dielectric fill 206, and/or substrate 201. Any suitable dry isotropic metal etch process may be used to laterally etch gate foot structures 219 and form lobe recesses 224.

FIG. 2L illustrates another cross-section view of the structure shown in FIG. 2K following the removal of any exposed gate dielectric 214, according to some embodiments. In some examples, the exposed portions of gate dielectric 214 that had been directly abutting gate foot structures 219 become contaminated with metal ions during the removal of gate foot structures 219. Accordingly, such portions of gate dielectric 214 may be removed using any suitable isotropic etching process that can remove high-k materials, such as hafnium oxide.

FIG. 2M illustrates another cross-section view of the structure shown in FIG. 2L following the deposition of a dielectric liner 226 and dielectric fill 228 to form the gate cut dielectric structure, according to some embodiments. According to some embodiments, dielectric liner 226 includes a high-k dielectric material, such as silicon nitride or silicon carbide or any other material having a dielectric constant of at least 6.5. Dielectric liner 226 may be, for example, conformally deposited using ALD to a thickness between about 2 nm and about 4 nm. Dielectric fill 228 may be formed directly on dielectric liner 226. According to some embodiments, dielectric fill 228 includes a low-k dielectric material, such as silicon dioxide or flowable oxide or any other material having a dielectric constant of at most 4.5. Dielectric fill 228 may be deposited using any suitable plasma deposition technique, such as via CVD. In still other example embodiments, dielectric fill 228 may be conformally deposited using ALD or CVD so as to pinch-off and close at the narrow portion toward the bottom of gate cut recess 218. In some embodiments, a single dielectric material is used to substantially fill the volume of gate cut recess 218 and lobe recesses 224. Dielectric fill 228 may overflow out of gate cut recess 218 and be polished back using chemical mechanical polishing (CMP), according to some embodiments. In the illustrated example, dielectric fill 228 is polished back to be substantially level with a top surface of gate cap 217.

According to some embodiments, the deposition of dielectric liner 226 and dielectric fill 228 within lobe recesses 224 forms lobe structures 230. Lobe structures 230 may include any number of dielectric materials used to fill the remaining portions of the gate cut structure. In some examples, a single dielectric material substantially fills the entire volume of lobe structures 230. Distal ends of lobe structures 230 may contact a portion of the adjacent subfins 208, according to some embodiments. Due to their location in replacing gate foot structures, a top surface of lobe structures 230 contacts gate electrode 216 while a bottom surface of lobe structures 230 contacts dielectric fill 206, according to some embodiments. A portion of gate dielectric 214 may contact an edge of lobe structures 230.

FIG. 2N illustrates another cross-section view of the structure shown in FIG. 2M following the formation of a conductive via 232 through the gate cut, according to some embodiments. Conductive via 232 may be formed through a central portion of the gate cut, such as through a central axis of the gate cut that extends along the height of the gate cut in the third direction. In some embodiments, conductive via 232 is formed through the entire height of dielectric fill 228. Conductive via 232 may also punch through a bottom portion of dielectric liner 226. Conductive via 232 may include any suitable conductive material, such as tungsten, ruthenium, molybdenum, or cobalt. In some embodiments, conductive via 232 includes a liner or barrier layer directly on the inner walls of dielectric fill 228 and a conductive fill material on the liner or barrier layer. The liner or barrier layer may include, for example, nitrogen along with tantalum or titanium, or other suitable liner or barrier materials.

FIG. 2O illustrates another cross-section view of the structure shown in FIG. 2N following the backside removal of substrate 201, according to some embodiments. Once all front-side processes have been performed across the integrated circuit, substrate 201 may be removed via any arrangement of grinding, polishing, and/or chemical etching processes. According to some embodiments, all materials are removed from the backside up until at least a bottom surface of dielectric fill 206 is exposed. Accordingly, a bottom portion of the gate cut structure may be exposed as well, including a bottom surface of conductive via 232.

FIG. 2P illustrates another cross-section view of the structure shown in FIG. 2O following the formation of a backside interconnect layer, according to some embodiments. In some examples, subfins 208 are first removed and replaced with dielectric material 234, which may include any number of dielectric layers. A backside interconnect layer may be formed that includes a backside dielectric layer 236 and a backside conductive layer 238. Backside dielectric layer 236 may include any suitable dielectric material, such as silicon dioxide. Backside conductive layer 238 may include any suitable conductive material, such as tungsten, ruthenium, molybdenum, or cobalt. In some examples, backside conductive layer 238 includes the same conductive material as conductive via 232. Conductive via directly contacts backside conductive layer 238 to provide backside signal or power routing, according to some embodiments.

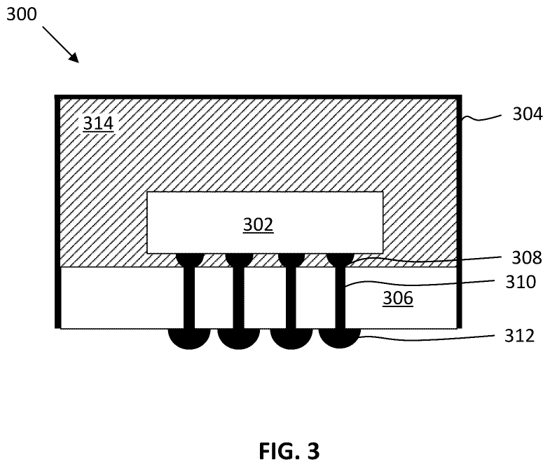

FIG. 3 illustrates an example embodiment of a chip package 300, in accordance with an embodiment of the present disclosure. As can be seen, chip package 300 includes one or more dies 302. One or more dies 302 may include at least one integrated circuit having semiconductor devices, such as any of the semiconductor devices disclosed herein. One or more dies 302 may include any other circuitry used to interface with other devices formed on the dies, or other devices connected to chip package 300, in some example configurations.

As can be further seen, chip package 300 includes a housing 304 that is bonded to a package substrate 306. The housing 304 may be any standard or proprietary housing, and may provide, for example, electromagnetic shielding and environmental protection for the components of chip package 300. The one or more dies 302 may be conductively coupled to a package substrate 306 using connections 308, which may be implemented with any number of standard or proprietary connection mechanisms, such as solder bumps, ball grid array (BGA), pins, or wire bonds, to name a few examples. Package substrate 306 may be any standard or proprietary package substrate, but in some cases includes a dielectric material having conductive pathways (e.g., including conductive vias and lines) extending through the dielectric material between the faces of package substrate 306, or between different locations on each face. In some embodiments, package substrate 306 may have a thickness less than 1 millimeter (e.g., between 0.1 millimeters and 0.5 millimeters), although any number of package geometries can be used. Additional conductive contacts 312 may be disposed at an opposite face of package substrate 306 for conductively contacting, for instance, a printed circuit board (PCB). One or more vias 310 extend through a thickness of package substrate 306 to provide conductive pathways between one or more of connections 308 to one or more of contacts 312. Vias 310 are illustrated as single straight columns through package substrate 306 for ease of illustration, although other configurations can be used (e.g., damascene, dual damascene, through-silicon via, or an interconnect structure that meanders through the thickness of substrate 306 to contact one or more intermediate locations therein). In still other embodiments, vias 310 are fabricated by multiple smaller stacked vias, or are staggered at different locations across package substrate 306. In the illustrated embodiment, contacts 312 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 312, to inhibit shorting.

In some embodiments, a mold material 314 may be disposed around the one or more dies 302 included within housing 304 (e.g., between dies 302 and package substrate 306 as an underfill material, as well as between dies 302 and housing 304 as an overfill material). Although the dimensions and qualities of the mold material 314 can vary from one embodiment to the next, in some embodiments, a thickness of mold material 314 is less than 1 millimeter. Example materials that may be used for mold material 314 include epoxy mold materials, as suitable. In some cases, the mold material 314 is thermally conductive, in addition to being electrically insulating.

### Methodology

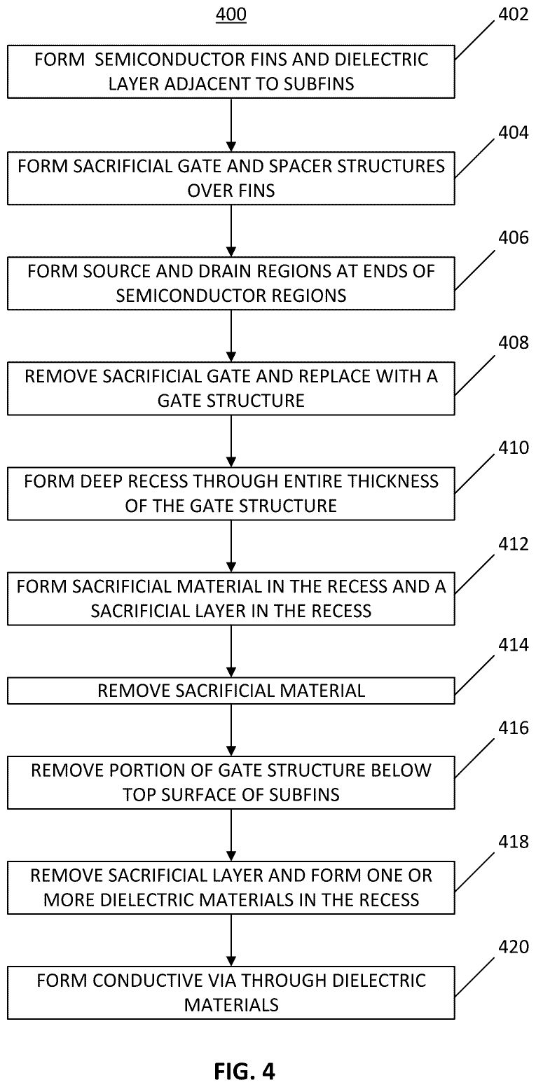

FIG. 4 is a flow chart of a method 400 for forming at least a portion of an integrated circuit, according to an embodiment. Various operations of method 400 may be illustrated in FIGS. 2A-2P. However, the correlation of the various operations of method 400 to the specific components illustrated in the aforementioned figures is not intended to imply any structural and/or use limitations. Rather, the aforementioned figures provide one example embodiment of method 400. Other operations may be performed before, during, or after any of the operations of method 400. For example, method 400 does not explicitly describe all processes that are performed to form common transistor structures. Some of the operations of method 400 may be performed in a different order than the illustrated order.

Method 400 begins with operation 402 where any number of parallel semiconductor fins are formed, according to some embodiments. The semiconductor material in the fins may be formed from a substrate such that the fins are an integral part of the substrate (e.g., etched from a bulk silicon substrate). Alternatively, the fins can be formed of material deposited onto an underlying substrate. In one such example case, a blanket layer of silicon germanium (SiGe) can be deposited onto a silicon substrate, and then patterned and etched to form a plurality of SiGe fins extending from that substrate. In another such example, the fins include alternating layers of material (e.g., alternating layers of silicon and SiGe) that facilitates forming of nanowires and nanoribbons during a gate forming process where one type of the alternating layers are selectively etched away so as to liberate the other type of alternating layers within the channel region, so that a gate-all-around (GAA) process can then be carried out. The alternating layers can be blanket deposited and then etched into fins, or deposited into fin-shaped trenches. The fins may also include a cap structure over each fin that is used to define the locations of the fins during, for example, an RIE process. The cap structure may be a dielectric material, such as silicon nitride.

According to some embodiments, a dielectric layer is formed around subfin portions of the one or more fins. In some embodiments, the dielectric layer extends between each pair of adjacent parallel fins and runs lengthwise in the same direction as the fins. In some embodiments, the anisotropic etching process that forms the fins also etches into a portion of the substrate and the dielectric layer may be formed within the recessed portions of the substrate. Accordingly, the dielectric layer acts as shallow trench isolation (STI) between adjacent fins. The dielectric layer may be any suitable dielectric material, such as silicon dioxide.

Method 400 continues with operation 404 where a sacrificial gate and spacer structures are formed over the fins. The sacrificial gate may be patterned using a gate masking layer in a strip that runs orthogonally over the fins (many gate masking layers and corresponding sacrificial gates may be formed parallel to one another (e.g., forming a crosshatch pattern with the fins). The gate masking layer may be any suitable hard mask material, such as CHM or silicon nitride. The sacrificial gate may be formed from any suitable material that can be selectively removed at a later time without damaging the semiconductor material of the fins. In one example, the sacrificial gate includes polysilicon. The spacer structures may be deposited and then etched back such that the spacer structures remain mostly only on sidewalls of any exposed structures. According to some embodiments, the spacer structures may be any suitable dielectric material, such as silicon nitride or silicon oxynitride.

Method 400 continues with operation 406 where source or drain regions are formed at the ends of the semiconductor regions of each of the fins. Any portions of the fins not protected by the sacrificial gate and spacer structures may be removed using, for example, an anisotropic etching process followed by the epitaxial growth of the source or drain regions from the exposed ends of the semiconductor layers in the fins. In some example embodiments, the source or drain regions are NMOS source or drain regions (e.g., epitaxial silicon) or PMOS source or drain regions (e.g., epitaxial SiGe). Another dielectric fill may be formed adjacent to the various source or drain regions for additional electrical isolation between adjacent regions. The dielectric fill may also extend over a top surface of the source or drain regions. In some embodiments, topside conductive contacts may be formed through the dielectric fill to contact one or more of the source or drain regions.

Method 400 continues with operation 408 where the sacrificial gate is removed and replaced with a gate structure. The sacrificial gate may be removed using an isotropic etching process that selectively removes all of the material from the sacrificial gate, thus exposing the various fins between the set of spacer structures. In the example case where GAA transistors are used, any sacrificial layers within the exposed fins between the spacer structures may also be removed to release nanoribbons, nanosheets, or nanowires of semiconductor material.

The gate structure may include both a gate dielectric and a gate electrode. The gate dielectric is first formed over the exposed semiconductor regions between the spacer structures followed by forming the gate electrode within the remainder of the trench between the spacer structures, according to some embodiments. The gate dielectric may include any number of dielectric layers deposited using a CVD process, such as ALD. The gate electrode can include any number of conductive material layers, such as any metals, metal alloys, or polysilicon. The gate electrode may be deposited using electroplating, electroless plating, CVD, ALD, PECVD, or PVD, to name a few examples. In some embodiments, the gate electrode may be recessed, and a dielectric gate cap is formed within the recessed area. The dielectric gate cap may have a thickness between 10 nm and 20 nm, such as around 15 nm. According to some embodiments, portions of the gate structure (e.g., gate foot structures) extend below the top surface of the subfins and between adjacent subfins along a given gate trench. These gate foot structures contribute to unwanted parasitic capacitance while contributing little to nothing to the device current through the semiconductor channel region.

Method 400 continues with operation 410 where a deep recess is formed through an entire thickness of the gate structure. A mask structure may be formed over the gate structure and an opening may be formed through the mask structure to expose a portion of the underlying gate electrode. According to some embodiments, the opening through the mask structure is at a location where the deep recess is to be formed through the underlying gate electrode. The mask structure may include any number of hard mask layers, such as any dielectric layers or carbon hard mask layers. The opening may be formed using a directional RIE process. According to some embodiments, the deep recess has a high height-to-width aspect ratio of at least 6:1 and extends through at least an entire thickness of the gate structure. In some examples, the deep recess also extends through an entire thickness of the dielectric fill between devices and into the underlying substrate.

Method 400 continues with operation 412 where a sacrificial material (masking layer) is deposited within the recess and recessed to a desired height, followed by a sacrificial layer conformally deposited over the sacrificial material and along the sidewalls of the recess. The sacrificial material may be any suitable material that can be removed at a later time without damaging any surrounding materials (e.g., metal, semiconductor, or dielectric materials). In some examples, the sacrificial material is CHM. According to some embodiments, the sacrificial material is blanket deposited over the entire structure to fill the recess, and then recessed to remove the sacrificial material from the top surface of the structure and until a top surface of the sacrificial material within the recess is level with or below a top surface of the adjacent subfins. In some cases, the top surface of the sacrificial material may be above the lowest point of the top surface of the adjacent dielectric fill, such that the top surface of the sacrificial material is between the top surface of the subfins and the lowest point of the top surface of the adjacent dielectric fill. In still other cases, the top surface of the sacrificial material is about 10 nm to 30 nm below a bottommost surface of the channel region (e.g., 10 nm to 30 nm below the bottom surface of the lowest nanoribbon 212).

According to some embodiments, the sacrificial layer is conformally deposited, using ALD, along any exposed sidewall surfaces of the deep recess above the sacrificial material and on a top surface of the sacrificial material. The sacrificial layer may be any suitable material that can withstand metal etchants and be removed without damaging the underlying gate electrode. In some examples, the sacrificial layer includes aluminum oxide. In some examples, the sacrificial layer has a thickness between about 2 nm and about 10 nm.

Method 400 continues with operation 414 where the sacrificial material is removed, along with the horizontal portion of the sacrificial layer. The sacrificial material may be removed using an ashing process, or any other suitable etching process (e.g., selective isotropic etch). According to some embodiments, the sacrificial layer remains on the deep recess sidewalls following the removal of the sacrificial material. Furthermore, removing the sacrificial material exposes portions of the gate foot structures, according to some embodiments.

Method 400 continues with operation 416 where the gate foot structures are removed using a lateral (isotropic) etching process. According to some embodiments, a metal isotropic etching process is used to laterally etch the exposed gate foot structures beneath the sacrificial layer within the deep recess. The etch process may form lobe recesses extending from the sidewalls of the deep recess and in place of the gate foot structures. In some examples, more than one isotropic etch process may be used to etch through different metal materials (such as through different work function metals).

Method 400 continues with operation 418 where the remaining sacrificial layer is removed, and one or more dielectric materials are formed within the deep recess. The sacrificial layer may be removed using any suitable isotropic etching process that preferentially does not cause any damage to the underlying gate electrode. The one or more dielectric materials subsequently formed within the deep recess may also be formed within the lobe recesses to form dielectric lobe structures that extend away from the sidewalls of the dielectric structure within the deep recess. The one or more dielectric materials may include a conformal dielectric liner along edges of the deep recess and lobe recesses and a dielectric fill on the dielectric liner. The dielectric liner may have a higher dielectric constant compared to the dielectric fill. There may be airgaps or voids within the lobe recesses and/or within the deep recess itself, due to pinch-off during the fill deposition process and/or liner process.

Method 400 continues with operation 420 where a conductive via is formed through the one or more dielectric materials. According to some embodiments, the conductive via extends through an entire thickness of the deep recess in order to contact a backside conductive layer. The conductive via may also punch through a bottom portion of the dielectric liner in examples where a dielectric liner is present within the one or more dielectric materials. The conductive via may include any suitable conductive material, such as tungsten, ruthenium, molybdenum, or cobalt. The method may further include frontside and/or backside interconnect processing, so as to connect the conductive via to other locations within the integrated circuit.

### Example System

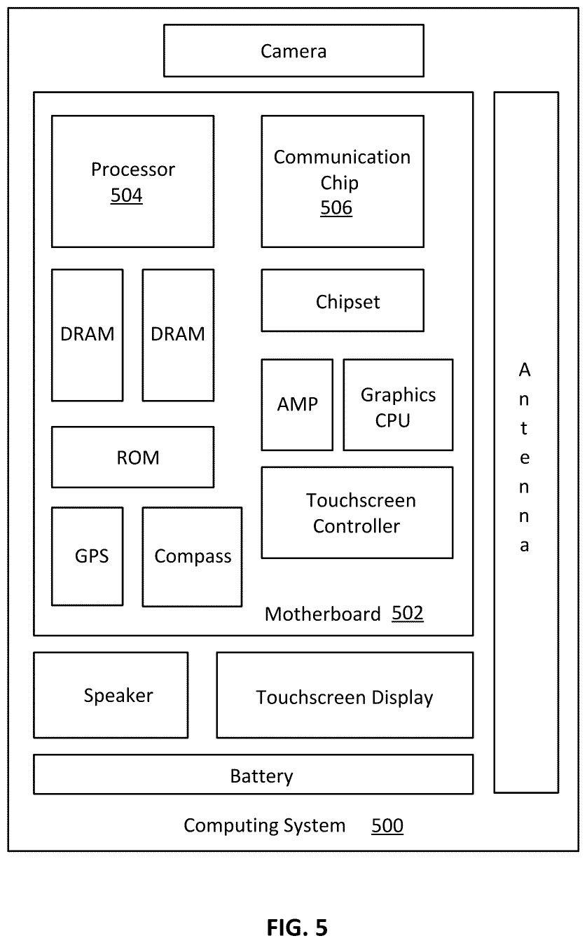

FIG. 5 is an example computing system implemented with one or more of the integrated circuit structures as disclosed herein, in accordance with some embodiments of the present disclosure. As can be seen, the computing system 500 houses a motherboard 502. The motherboard 502 may include a number of components, including, but not limited to, a processor 504 and at least one communication chip 506, each of which can be physically and electrically coupled to the motherboard 502, or otherwise integrated therein. As will be appreciated, the motherboard 502 may be, for example, any printed circuit board (PCB), whether a main board, a daughterboard mounted on a main board, or the only board of system 500, etc.

Depending on its applications, computing system 500 may include one or more other components that may or may not be physically and electrically coupled to the motherboard 502. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 500 may include one or more integrated circuit structures or devices configured in accordance with an example embodiment, such as a module including an integrated circuit on a substrate, the substrate having semiconductor devices that have one or more of their metal gate foot structures removed. In some embodiments, multiple functions can be integrated into one or more chips (e.g., for instance, note that the communication chip 506 can be part of or otherwise integrated into the processor 504).

The communication chip 506 enables wireless communications for the transfer of data to and from the computing system 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing system 500 includes an integrated circuit die packaged within the processor 504. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 506 also may include an integrated circuit die packaged within the communication chip 506. In accordance with some such example embodiments, the integrated circuit die of the communication chip includes one or more semiconductor devices as variously described herein. As will be appreciated in light of this disclosure, note that multi-standard wireless capability may be integrated directly into the processor 504 (e.g., where functionality of any chips 506 is integrated into processor 504, rather than having separate communication chips). Further note that processor 504 may be a chip set having such wireless capability. In short, any number of processor 504 and/or communication chips 506 can be used. Likewise, any one chip or chip set can have multiple functions integrated therein.

In various implementations, the computing system 500 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 500 may be combined or integrated in a system-on-a-chip (SoC) architecture. In some embodiments, the components may be hardware components, firmware components, software components or any suitable combination of hardware, firmware or software.

### Further Example Embodiments

The following examples pertain to further embodiments, from which numerous permutations and configurations will be apparent.

Example 1 is an integrated circuit that includes a semiconductor region extending from a source or drain region in a first direction, a gate structure extending over the semiconductor region in a second direction different from the first direction, a dielectric layer beneath the gate structure, and a dielectric structure extending in the first direction through the gate structure adjacent to the semiconductor region and extending in a third direction through an entire thickness of the gate structure and through at least a portion of an entire thickness of the dielectric layer. The dielectric structure includes walls that extend substantially in the third direction and abut the gate structure and one or more lobe structures that extend from the walls in the second direction such that a top portion of the one or more lobe structures contacts the gate structure and a bottom portion of the one or more lobe structures contacts the dielectric layer.

Example 2 includes the integrated circuit of Example 1, wherein the gate structure comprises a gate electrode and a gate dielectric, and wherein at least a portion of the gate dielectric contacts the one or more lobe structures.

Example 3 includes the integrated circuit of Example 2, wherein the gate dielectric comprises hafnium and oxygen.

Example 4 includes the integrated circuit of any one of Examples 1-3, wherein the dielectric structure comprises: a dielectric liner along edges of the walls and one or more lobe structures; and a dielectric fill on the dielectric liner.

Example 5 includes the integrated circuit of Example 4, wherein the dielectric liner comprises a material with a higher dielectric constant compared to the dielectric fill.

Example 6 includes the integrated circuit of any one of Examples 1-5, further comprising a conductive via extending in the third direction through the dielectric structure.

Example 7 includes the integrated circuit of Example 6, wherein the conductive via comprises tungsten, cobalt, molybdenum, or ruthenium.

Example 8 includes the integrated circuit of Example 6 or 7, further comprising a conductive layer on a bottom surface of the dielectric layer and contacting the conductive via.

Example 9 includes the integrated circuit of any one of Examples 1-8, wherein the one or more lobe structures include two lobe structures extending from opposite sides of the dielectric structure.

Example 10 includes the integrated circuit of any one of Examples 1-9, wherein the first direction is orthogonal to the second direction, and the third direction is orthogonal to the first and second directions.

Example 11 is a printed circuit board comprising the integrated circuit of any one of Examples 1-10.

Example 12 is an electronic device that includes a chip package having one or more dies. At least one of the one or more dies includes a semiconductor device having a semiconductor region extending in a first direction from a source or drain region, and a gate structure extending over the semiconductor region in a second direction different from the first direction, a dielectric layer beneath the gate structure, and a dielectric structure extending in the first direction through the gate structure adjacent to the semiconductor region and extending in a third direction through an entire thickness of the gate structure and through at least a portion of an entire thickness of the dielectric layer. The dielectric structure includes walls that extend substantially in the third direction and abut the gate structure and one or more lobe structures that extend from the walls in the second direction such that a top portion of the one or more lobe structures contacts the gate structure and a bottom portion of the one or more lobe structures contacts the dielectric layer.

Example 13 includes the electronic device of Example 12, wherein the gate structure comprises a gate electrode and a gate dielectric, and wherein at least a portion of the gate dielectric contacts the one or more lobe structures.

Example 14 includes the electronic device of Example 13, wherein the gate dielectric comprises hafnium and oxygen.

Example 15 includes the electronic device of any one of Examples 12-14, wherein the dielectric structure comprises: a dielectric liner along edges of the walls and one or more lobe structures; and a dielectric fill on the dielectric liner.

Example 16 includes the electronic device of Example 15, wherein the dielectric liner comprises a material with a higher dielectric constant compared to the dielectric fill.

Example 17 includes the electronic device of any one of Examples 12-16, wherein the at least one of the one or more dies further comprises a conductive via extending in the third direction through the dielectric structure.

Example 18 includes the electronic device of Example 17, wherein the conductive via comprises tungsten, cobalt, molybdenum, or ruthenium.

Example 19 includes the electronic device of Example 17 or 18, wherein the at least one of the one or more dies further comprises a conductive layer on a bottom surface of the dielectric layer and contacting the conductive via.

Example 20 includes the electronic device of any one of Examples 12-19, wherein the one or more lobe structures consists of two lobe structures extending from opposite sides of the dielectric structure.

Example 21 includes the electronic device of any one of Examples 12-20, wherein the first direction is orthogonal to the second direction, and the third direction is orthogonal to the first and second directions.

Example 22 includes the electronic device of any one of Examples 12-21, further comprising a printed circuit board, wherein the chip package is attached to the printed circuit board.

Example 23 is a method of forming an integrated circuit. The method includes forming a multilayer fin extending in a first direction over a substrate having a first section with first material layers alternating with second material layers, and a subfin beneath the first section; forming a dielectric layer adjacent to the subfin; forming a gate structure extending in a second direction over the first material layers after removing the second material layers of the multilayer fin, wherein a portion of the gate structure extends below a top surface of the subfin; forming a recess adjacent to the first material layers and the subfin and through an entire thickness of the gate structure and at least a portion of an entire thickness of the dielectric layer; forming a sacrificial material at a bottom portion of the recess, such that a top surface of the sacrificial material is below a top surface of the subfin; forming a sacrificial liner above the sacrificial material on sidewalls within the recess; removing the sacrificial material; removing the portion of the gate structure extending below the top surface of the subfin; removing the sacrificial liner; and forming one or more dielectric materials within the recess.

Example 24 includes the method of Example 23, wherein the gate structure comprises a gate dielectric and a gate electrode, wherein removing the portion of the gate structure comprises first removing a portion of the gate electrode followed by removing a portion of the gate dielectric.

Example 25 includes the method of Example 23 or 24, wherein removing the portion of the gate structure comprises isotropically etching the portion of the gate structure.

Example 26 includes the method of any one of Examples 23-25, wherein forming the one or more dielectric materials comprises forming a dielectric liner along edges of the recess and forming a dielectric fill on the dielectric liner.

Example 27 includes the method of any one of Examples 23-26, further comprising forming a conductive via through an entire thickness of the recess, such that the one or more dielectric materials are between the conductive via and the gate structure.

Example 28 is an integrated circuit that includes a semiconductor region extending from a source or drain region in a first direction, a gate structure extending over the semiconductor region in a second direction different from the first direction, a dielectric layer beneath the gate structure, a dielectric structure extending in the first direction through the gate structure adjacent to the semiconductor region and extending in a third direction through an entire thickness of the gate structure and through at least a portion of an entire thickness of the dielectric layer, and a conductive via extending through an entire thickness of the dielectric structure in the third direction. The dielectric structure includes walls extending substantially in the third direction and at least one lobe structure extending in the second direction from at least one of the walls. The dielectric structure also includes a dielectric liner along an outer edge of the walls and the at least one lobe structure of the dielectric structure and a dielectric fill on the dielectric liner.

Example 29 includes the integrated circuit of Example 28, wherein the gate structure comprises a gate electrode and a gate dielectric, and wherein at least a portion of the gate dielectric contacts the at least one lobe structure.

Example 30 includes the integrated circuit of Example 29, wherein the gate dielectric comprises hafnium and oxygen.

Example 31 includes the integrated circuit of any one of Examples 28-30, wherein the dielectric liner comprises a material with a higher dielectric constant compared to the dielectric fill.

Example 32 includes the integrated circuit of any one of Examples 28-31, wherein the conductive via comprises tungsten, cobalt, molybdenum, or ruthenium.

Example 33 includes the integrated circuit of any one of Examples 28-32, further comprising a conductive layer on a bottom surface of the dielectric layer and contacting the conductive via.

Example 34 includes the integrated circuit of any one of Examples 28-33, wherein the at least one lobe structure comprises two lobe structures extending from opposite sides of the dielectric structure.

Example 35 includes the integrated circuit of any one of Examples 28-34, wherein the first direction is orthogonal to the second direction, and the third direction is orthogonal to the first and second directions.

Example 36 is a printed circuit board comprising the integrated circuit of any one of Examples 28-35.

Example 37 includes the subject matter of any one of Examples 1 through 36, wherein the semiconductor region comprises one or more semiconductor nanoribbons, nanowires, or nanosheets. In another such example, the semiconductor region comprises a semiconductor fin.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit comprising:
a semiconductor region extending from a source or drain region in a first direction;
a gate structure extending over the semiconductor region in a second direction different from the first direction;
a dielectric layer beneath the gate structure; and
a dielectric structure extending in the first direction through the gate structure adjacent to the semiconductor region and extending in a third direction through an entire thickness of the gate structure and through at least a portion of the dielectric layer, wherein the dielectric structure comprises
walls that extend substantially in the third direction and abut the gate structure, and
one or more lobe structures that extend from the walls in the second direction such that a top portion of the one or more lobe structures contacts the gate structure and a bottom portion of the one or more lobe structures contacts the dielectric layer.

2. The integrated circuit of claim 1, wherein the gate structure comprises a gate electrode and a gate dielectric, and wherein at least a portion of the gate dielectric contacts the one or more lobe structures.

3. The integrated circuit of claim 1, wherein the dielectric structure comprises:
a dielectric liner along edges of the walls and one or more lobe structures; and
a dielectric fill on the dielectric liner.

4. The integrated circuit of claim 3, wherein the dielectric liner comprises a material with a higher dielectric constant compared to the dielectric fill.

5. The integrated circuit of claim 1, further comprising a conductive via extending in the third direction through the dielectric structure.

6. The integrated circuit of claim 5, further comprising a conductive layer on a bottom surface of the dielectric layer and contacting the conductive via.

7. The integrated circuit of claim 1, wherein the one or more lobe structures include two lobe structures extending from opposite sides of the dielectric structure.

8. A printed circuit board comprising the integrated circuit of claim 1.

9. An electronic device, comprising:
a chip package comprising one or more dies, at least one of the one or more dies comprising
a semiconductor device having a semiconductor region extending in a first direction from a source or drain region, and a gate structure extending over the semiconductor region in a second direction different from the first direction;
a dielectric layer beneath the gate structure; and
a dielectric structure extending in the first direction through the gate structure adjacent to the semiconductor region and extending in a third direction through an entire thickness of the gate structure and through at least a portion of an entire thickness of the dielectric layer, wherein the dielectric structure comprises
walls that extend substantially in the third direction and abut the gate structure,
one or more lobe structures that extend from the walls in the second direction such that a top portion of the one or more lobe structures contacts the gate structure and a bottom portion of the one or more lobe structures contacts the dielectric layer.

10. The electronic device of claim 9, wherein the gate structure comprises a gate electrode and a gate dielectric, and wherein at least a portion of the gate dielectric contacts the one or more lobe structures.

11. The electronic device of claim 9, wherein the dielectric structure comprises:
a dielectric liner along edges of the walls and one or more lobe structures; and
a dielectric fill on the dielectric liner.

12. The electronic device of claim 9, wherein the at least one of the one or more dies further comprises a conductive via extending in the third direction through the dielectric structure.

13. The electronic device of claim 12, wherein the at least one of the one or more dies further comprises a conductive layer on a bottom surface of the dielectric layer and contacting the conductive via.

14. The electronic device of claim 9, further comprising a printed circuit board, wherein the chip package is attached to the printed circuit board.

15. An integrated circuit comprising:
a semiconductor region extending from a source or drain region in a first direction;
a gate structure extending over the semiconductor region in a second direction different from the first direction;
a dielectric layer beneath the gate structure;
a dielectric structure extending in the first direction through the gate structure adjacent to the semiconductor region and extending in a third direction through an entire thickness of the gate structure and through at least a portion of an entire thickness of the dielectric layer, wherein the dielectric structure includes walls extending substantially in the third direction and at least one lobe structure extending in the second direction from at least one of the walls, wherein the dielectric structure comprises
a dielectric liner along an outer edge of the walls and the at least one lobe structure of the dielectric structure, and
a dielectric fill on the dielectric liner; and
a conductive via extending through an entire thickness of the dielectric structure in the third direction.

16. The integrated circuit of claim 15, wherein the gate structure comprises a gate electrode and a gate dielectric, and wherein at least a portion of the gate dielectric contacts the at least one lobe structure.

17. The integrated circuit of claim 15, wherein the dielectric liner comprises a material with a higher dielectric constant compared to the dielectric fill.

18. The integrated circuit of claim 15, further comprising a conductive layer on a bottom surface of the dielectric layer and contacting the conductive via.

19. The integrated circuit of claim 15, wherein the at least one lobe structure consists of two lobe structures extending from opposite sides of the dielectric structure.

20. The integrated circuit of claim 15, wherein the first direction is orthogonal to the second direction, and the third direction is orthogonal to the first and second directions.
